(19) United States
(12) Patent Application Publication
(10) Pub. No.: US 2015/0034903 A1
(43) Pub. Date: Feb. 5, 2015

(54) SEMICONDUCTOR DEVICE AND METHOD OF MANUFACTURING SEMICONDUCTOR DEVICE

(71) Applicant: KABUSHIKI KAISHA TOSHIBA, Tokyo (JP)

(72) Inventors: Hidetoshi FUJIMOTO, Kanagawa (JP); Yasunobu SAITO, Ishikawa (JP); Akira YOSHIOKA, Ishikawa (JP)

(73) Assignee: KABUSHIKI KAISHA TOSHIBA, Tokyo (JP)

(21) Appl. No.: 14/194,441

(22) Filed: Feb. 28, 2014

(30) Foreign Application Priority Data
Aug. 5, 2013 (JP) 2013-162550

(51) Int. Cl. H01L 29/78; H01L 21/02; H01L 29/20

(52) U.S. Cl. CPC H01L 29/7827; H01L 29/2003; H01L 21/0254
USPC 257/20; 438/478

(57) ABSTRACT

A semiconductor device includes a first layer made of a group III nitride semiconductor of a first conductivity type, a second layer made of a group III nitride semiconductor of a second conductivity type on a first surface of the first layer, a third layer made of a group III nitride semiconductor of the first conductivity type on a first region of a surface of the second layer, a gate electrode extending through the second layer and the third layer and the first surface of the first layer, and insulated from the first, second, and third layers, a first electrode in contact with the third layer, a second electrode in contact with a second region of the surface of the second layer that is different from the first region, and a third electrode provided on a side of a second surface of the first layer.

### CROSS-REFERENCE TO RELATED APPLICATION

This application is based upon and claims the benefit of priority from Japanese Patent Application No. 2013-162550, filed Aug. 5, 2013, the entire contents of which are incorporated herein by reference.

### FIELD

Embodiments described herein relate to a semiconductor device and a method of manufacturing a semiconductor device.

### BACKGROUND

Conventionally, a semiconductor power device is used in a power amplifier, a power source circuit, a motor drive circuit and the like. For such uses, it is desirable for the semiconductor power device to possess high breakdown voltage, high-speed switching and low ON resistance. A nitride semiconductor element has been developed to meet such requirements.

One such nitride semiconductor element is a gallium nitride (GaN)-based semiconductor element which employs a heterojunction, e.g., a high electron mobility transistor (HEMT) or a heterojunction field effect transistor (HFET).

Conventionally, when forming an n-type GaN layer, an n-type impurity is injected into a part of a p-type GaN layer by ion implantation. In this case, however, an n-type impurity is injected into a p-type region and hence, there exists a possibility that the resistance of the n-type GaN layer is increased. On the other hand, when the concentration of an n-type impurity in the p-type GaN layer is lowered so as to lower the resistance of the n-type GaN layer, the contact resistance between the p-type GaN layer and an electrode formed on the p-type GaN layer is increased. Accordingly, it is difficult to realize low ON resistance in a GaN-based semiconductor element having a vertical structure.

### DESCRIPTION OF THE DRAWINGS

FIG. 1 is a cross-sectional view showing one example configuration of a vertical GaN semiconductor device according to a first embodiment.

FIG. 2 is a cross-sectional view showing one example of a step of a method of manufacturing the semiconductor device according to the first embodiment.

FIG. 3 is a cross-sectional view showing a step of the manufacturing method succeeding the step shown in FIG. 2.

FIG. 4 is a cross-sectional view showing a step of the manufacturing method succeeding the step shown in FIG. 3.

FIG. 5 is a cross-sectional view showing a step of the manufacturing method succeeding the step shown in FIG. 4.

FIG. 6 is a cross-sectional view showing one example configuration of a vertical GaN semiconductor device according to a second embodiment.

FIG. 7 is a cross-sectional view showing one example of a step of a method of manufacturing the semiconductor device according to the second embodiment.

FIG. 8 is a cross-sectional view showing a step of the manufacturing method succeeding the step shown in FIG. 7.

FIG. 9 is a cross-sectional view showing one example configuration of a vertical GaN semiconductor device according to a third embodiment.

### DETAILED DESCRIPTION

According to an embodiment, there is provided a semiconductor device using a group III nitride semiconductor which exhibits low ON resistance.

In general, according to one embodiment, a semiconductor device includes a first layer made of a group III nitride semiconductor of a first conductivity type, a second layer made of a group III nitride semiconductor of a second conductivity type on a first surface of the first layer, a third layer made of a group III nitride semiconductor of the first conductivity type on a first region of a surface of the second layer, a gate electrode extending through the second layer and the third layer and the first surface of the first layer, and insulated from the first, second, and third layers, a first electrode in contact with the third layer, a second electrode in contact with a second region of the surface of the second layer that is different from the first region, and a third electrode provided on a side of a second surface of the first layer that is opposite to the first surface.

Hereinafter, exemplary embodiments are explained in conjunction with the drawings. The present disclosure is not limited to these embodiments. In the embodiments explained hereinafter, the vertical direction of a semiconductor substrate depicts the relative direction when a surface of the semiconductor device on which a semiconductor element is formed forms an upper surface such that there may be cases where the vertical direction as depicted in the embodiments differs from the vertical direction determined in accordance with gravitational acceleration.

In the embodiments explained hereinafter, gallium nitride (GaN) is used as a group III nitride semiconductor. However, aluminum nitride (AlN), indium nitride (InN) and their mixed crystal may be used as the group III nitride semiconductor in place of gallium nitride (GaN). Hereinafter, the explanation is made with respect to the case where the group III nitride semiconductor is gallium nitride (GaN).

### First Embodiment

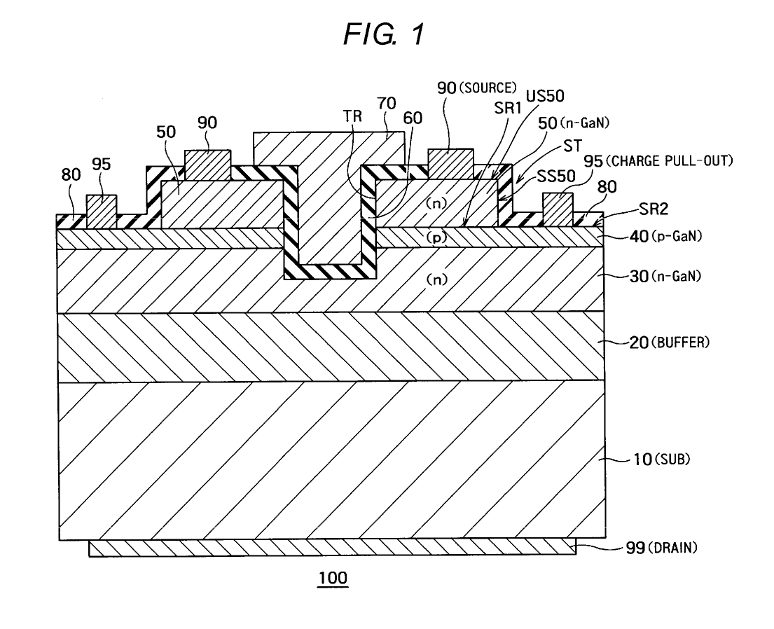

FIG. 1 is a cross-sectional view showing one example configuration of a vertical GaN semiconductor device 100 (hereinafter, also referred to as a semiconductor device 100) according to a first embodiment. The semiconductor device 100 includes: a substrate 10; a buffer layer 20; an n-type GaN layer 30; a p-type GaN layer 40; an n-type GaN layer 50; a gate insulator 60; a gate electrode 70; an interlayer insulator 80; a source electrode 90; a charge pull-out electrode 95; and a drain electrode 99.

The substrate 10 is a silicon substrate, a GaN substrate, an SiC substrate or the like, for example. Although a conductivity type of the substrate 10 is not limited to any one type, it is preferable that the substrate 10 have the same conductivity type as the GaN layer 30 (e.g., n-type). Hereinafter, the explanation is made with respect to the case where the n-type silicon substrate is used as the substrate 10 as an example.

The buffer layer 20 is formed on a surface (first surface) of the substrate 10. The buffer layer 20 has a superlattice structure where a layer made of AlN and a layer made of GaN are alternately laminated on each other, for example. The buffer layer 20 may be also formed using a composition gradient AlGaN layer where the Al content ratio in AlGaN is gradually lowered along the direction from the surface of the substrate 10 toward the n-type GaN layer 30. By interposing the buffer layer 20 between the substrate 10 and the laminated structural body (30, 40 and 50), it is possible to suppress the distortion and warping of the semiconductor device 100. The buffer layer 20 enhances crystallinity of a laminated structural body including the n-type GaN layer 30, the p-type GaN layer 40 and the n-type GaN layer 50 which are formed on the buffer layer 20, and also lowers resistance in the vertical direction. A thickness of the n-type GaN layer 50 is set to approximately 100 nm to 200 nm, for example.

The n-type GaN layer 30 which constitutes a first layer is formed on the buffer layer 20. The n-type GaN layer 30 is formed using GaN containing an n-type impurity (for example, silicon (Si), germanium (Ge)). The p-type GaN layer 40 which constitutes a second layer is formed on the n-type GaN layer 30. The p-type GaN layer 40 is formed using GaN containing a p-type impurity (for example, magnesium (Mg)). The n-type GaN layer 50 which constitute a third layer is partially formed on a first region SR1 of a surface of the p-type GaN layer 40. The n-type GaN layer 50 is formed using GaN containing an n-type impurity. The n-type GaN layer 30, the p-type GaN layer 40, and the n-type GaN layer 50 form the laminated structural body made of GaN. Although a thickness of the laminated structural body made of GaN and a thickness of the buffer layer 20 change depending on the specification of the semiconductor device 100, these thicknesses are preferably set to approximately 3 μm or more to impart a breakdown strength of 600V, for example, to the semiconductor device 100.

A trench TR is formed such that the trench TR penetrates the p-type GaN layer 40 from a surface of the n-type GaN layer 50 and reaches the n-type GaN layer 30. The gate insulator 60 is formed such that the gate insulator 60 covers an inner surface of the trench TR and a part of a front surface US50 of the n-type GaN layer 50. The gate insulator 60 is formed using an insulation film such as a silicon oxide film, for example. The gate electrode 70 is embedded in the trench TR on the gate insulator 60. The gate electrode 70 is formed using a metal laminated film such as an Au/Ni film or a conductive material such as doped polysilicon, for example. Accordingly, the gate electrode 70 functions as a trench gate electrode which penetrates the p-type GaN layer 40 from the front surface US50 of the n-type GaN layer 50 and reaches the n-type GaN layer 30. That is, one end of the gate electrode 70 is disposed above the front surface US50 of the n-type GaN layer 50 and the other end of the gate electrode 70 is disposed in the n-type GaN layer 30 through the p-type GaN layer 40.

The interlayer insulator 80 is formed on the front surfaces US50 and side surfaces SS50 of the n-type GaN layer 50 and a second region SR2 of the surface of the p-type GaN layer 40. The interlayer insulator 80 is formed using an insulation film such as a silicon oxide film, for example. The interlayer insulator 80 may be formed of the same material as the gate insulator 60, or may be formed of a material which differs from a material for forming the gate insulator 60.

The source electrode 90 which constitutes a first electrode is formed on the front surface US50 of the n-type GaN layer 50, and is connected with the n-type GaN layer 50 by ohmic bonding. It is sufficient that the source electrode 90 is made of a material which allows the source electrode 90 to be connected with the n-type GaN layer 50 by ohmic bonding, and is formed using a metal material such as TiAl, for example.

The charge pull-out electrode 95 is formed on the second region SR2 of the surface of the p-type GaN layer 40, and is connected with the p-type GaN layer 40 by ohmic bonding. The second region SR2 is a surface region of the surface of the p-type GaN layer 40 that is different from the first region SR1.

It is sufficient that the charge pull-out electrode 95 which constitutes a second electrode is made of a material which allows the charge pull-out electrode 95 to be connected with the p-type GaN layer 40 by ohmic bonding, and is formed using a metal laminated film such as an Au/Ni film, for example. In forming the charge pull-out electrode 95 using the metal laminated film made of Au/Ni, an Ni layer is brought into contact with the p-type GaN layer 40 as a lower layer of the charge pull-out electrode 95, and an Au layer is formed on the Ni layer. Due to such structure, the charge pull-out electrode 95 can be connected to the p-type GaN layer 40 by ohmic bonding, and forms a low-resistance electrode.

The drain electrode 99 which constitutes a third electrode is formed on a back surface (second surface) of the substrate 10. The drain electrode 99 is formed using a metal material such as Ti/Al, for example, in the same manner as the source electrode 90.

The semiconductor device 100 is a vertical FET so that a channel is formed in a portion of the p-type GaN layer 40 in the vicinity of the gate insulator 60. Accordingly, by controlling a voltage of the gate electrode 70, a channel is formed in a boundary portion between the gate insulator 60 and the p-type GaN layer 40. An electric current from the drain electrode 99 flows though the channel via the substrate 10, the buffer layer 20 and the n-type GaN layer 30 and, then, flows to the source electrode 90 through the n-type GaN layer 50.

When the p-type GaN layer 40 is brought into a floating state, there exists a possibility that holes are stored in the p-type GaN layer 40 so that avalanche breakdown occurs in the semiconductor device 100. The charge pull-out electrode 95 becomes necessary to prevent the occurrence of such avalanche breakdown. The charge pull-out electrode 95 is fixed at a predetermined voltage (for example, ground potential), and has a function of pulling out holes stored in the p-type GaN layer 40.

Here, a stepped portion ST is explained. The n-type GaN layer 50 according to this embodiment is formed on the first region SR1 of the surface of the p-type GaN layer 40, but is not formed on the second region SR2 of the surface of the p-type GaN layer 40. That is, the n-type GaN layer 50 is partially formed on the surface of the p-type GaN layer 40 and does not cover the whole surface of the p-type GaN layer 40. Accordingly, between the first region SR1 and the second region SR2, there exists the stepped portion ST which is formed by the n-type GaN layer 50 and the p-type GaN layer 40. In the stepped portion ST, the second region SR2 of the surface of the p-type GaN layer 40 forms a lower step and the front surface US50 of the n-type GaN layer 50 forms an upper step. There exists the side surface SS50 of the n-type GaN layer 50 between the lower step and the upper step of the stepped portion ST. Accordingly, the stepped portion ST is formed by the second region SR2 of the surface of the p-type GaN layer 40, the side surface SS50 of the n-type GaN layer 50, and the front surface US50 of the n-type GaN layer 50.

Due to the formation of the stepped portion ST, the source electrode 90 can be formed on the front surface US50 of the n-type GaN layer 50 (the upper step of the stepped portion ST), and the charge pull-out electrode 95 can be formed on the second region SR2 of the p-type GaN layer 40 (the lower step of the stepped portion ST). That is, due to the formation of the stepped portion ST, regions where the source electrode 90 and the charge pull-out electrode 95 are formed can be ensured thus facilitating the formation of the source electrode 90 and the charge pull-out electrode 95. Accordingly, the occurrence of avalanche breakdown can be prevented and hence, the semiconductor device 100 can maintain high breakdown voltage.

For forming the n-type GaN layer 50, for example, it may be possible to inject an n-type impurity (for example, Si, Ge) into the p-type GaN layer 40 by ion implantation. In this case, however, an n-type impurity is injected into the p-type region and hence, there exists a possibility that the resistance of the n-type GaN layer 50 is increased in a region where the impurity is injected by ion implantation.

On the contrary, according to this embodiment, the n-type GaN layer 50 is selectively epitaxially grown on the p-type GaN layer 40. Due to such processing, the region where the charge pull-out electrode 95 is formed can be ensured to be on the surface of the p-type GaN layer 40 and, at the same time, the resistance of the n-type GaN layer 50 can be lowered. That is, according to this embodiment, it is possible to realize the resistance of the n-type GaN layer 50 can be lowered and, at the same time, the region where the charge pull-out electrode 95 can be ensured for preventing the occurrence of avalanche breakdown. As a result, the semiconductor device 100 according to this embodiment can realize both the low ON resistance and the high breakdown voltage.

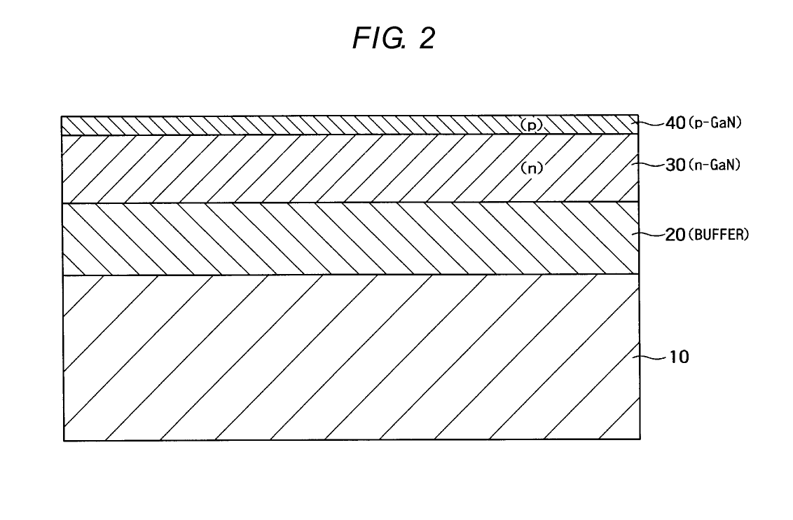

FIG. 2 to FIG. 5 are cross-sectional views showing one example of a method of manufacturing the semiconductor device 100 according to this embodiment. The method of manufacturing the semiconductor device 100 is explained in conjunction with FIG. 2 to FIG. 5.

Firstly, the buffer layer 20 is formed on the substrate 10 using a Metal-Organic Chemical Vapor Deposition (MOCVD) method. As described above, the buffer layer 20 has the superlattice structure made of AlN and GaN or a composition gradient AlGaN layer. For example, in the case of forming the superlattice structure made of AlN and GaN on the substrate 10, an AlN layer and a GaN layer are alternately laminated on the substrate 10 in the order of the AlN layer, the GaN layer, the AlN layer, the GaN layer, the AlN layer, the GaN layer . . . . Due to such constitution, the buffer layer 20 can absorb warping generated by the difference in lattice constant or the difference in thermal expansion coefficient between the substrate 10 and the n-type GaN layer 30. Further, the uppermost layer of the buffer layer 20 is formed of a GaN layer and hence, the n-type GaN layer 30 can be easily formed on the buffer layer 20.

For example, in the case of forming the composition gradient AlGaN layer on the substrate 10, AlGaN is deposited in such a manner that a content ratio of Al in AlGaN is initially set to 100%, the content ratio of Al is gradually lowered, and the content ratio of Al is set to 0% at the uppermost portion of the buffer layer 20. That is, Al is deposited on the substrate 10 at an initial stage of deposition of the buffer layer 20 and, thereafter, AlGaN is deposited on the substrate 10 while decreasing the Al content ratio and, GaN is deposited at a final stage. Due to such processing, an Al layer of the composition gradient AlGaN layer is brought into contact with a surface of the substrate 10, and a GaN layer of the composition gradient AlGaN layer is brought into contact with a bottom surface of the n-type GaN layer 30. Due to such constitution, the buffer layer 20 can absorb the warping generated by the difference in lattice constant or the difference in thermal expansion coefficient between the substrate 10 and the n-type GaN layer 30. Further, the n-type GaN layer 30 can be easily formed on the buffer layer 20.

Next, the n-type GaN layer 30 is deposited on the buffer layer 20 using an MOCVD method. Here, GaN is deposited while being doped with an n-type impurity (for example, Si, Ge) into GaN.

Next, the p-type GaN layer 40 is deposited on the n-type GaN layer 30 using a MOCVD method. Here, GaN is deposited while being doped with a p-type impurity (for example, Mg) into GaN. Due to such processing, the structure shown in FIG. 2 can be acquired.

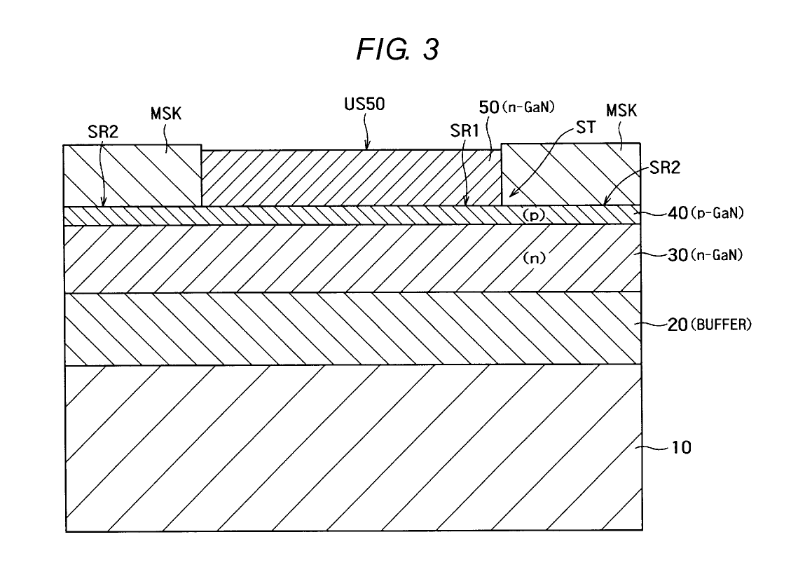

Next, as shown in FIG. 3, a mask layer MSK is formed on the second region SR2 of the surface of the p-type GaN layer 40 using a lithography technique and an etching technique. The mask layer MSK is formed of an insulation film such as a silicon oxide film, for example. Since the mask layer MSK covers the second region SR2, the n-type GaN layer 50 is not epitaxially grown on the second region SR2. On the other hand, the n-type GaN layer 50 is epitaxially grown on the first region SR1 where the mask layer MSK is not formed.

Next, using the mask layer MSK as a mask, GaN is epitaxially grown while being doped with an n-type impurity (for example, Si, Ge). Due to such processing, the n-type GaN layer 50 is selectively epitaxially grown on the first region SR1 of the surface of the p-type GaN layer 40. Due to such selective epitaxial growth of the n-type GaN layer 50, the stepped portion ST is formed as shown in FIG. 3. In the stepped portion ST, the second region SR2 of the p-type GaN layer 40 forms the lower step and the front surface US50 of the n-type GaN layer 50 forms the upper step.

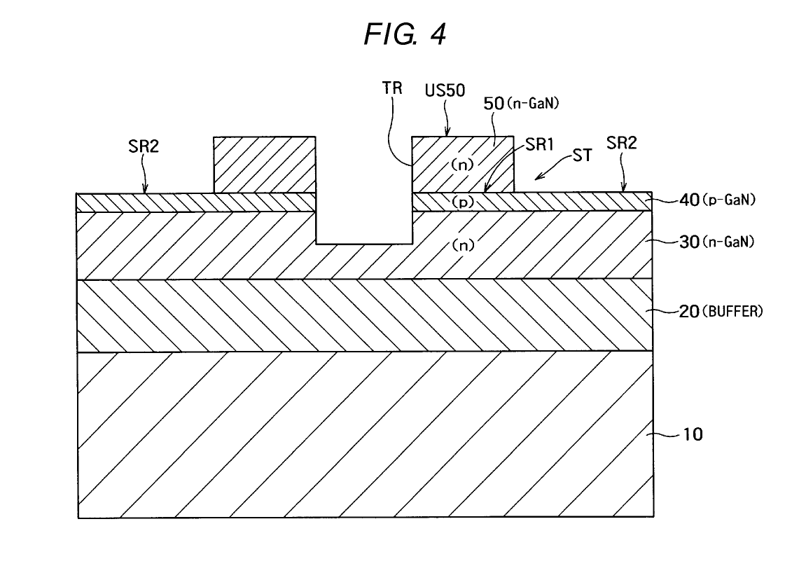

After the mask layer MSK is removed, using a lithography technique and an etching technique, the trench TR which penetrates the p-type GaN layer 40 from the front surface US50 of the n-type GaN layer 50 and reaches the n-type GaN layer 30 is formed. Due to such processing, the structure shown in FIG. 4 is acquired.

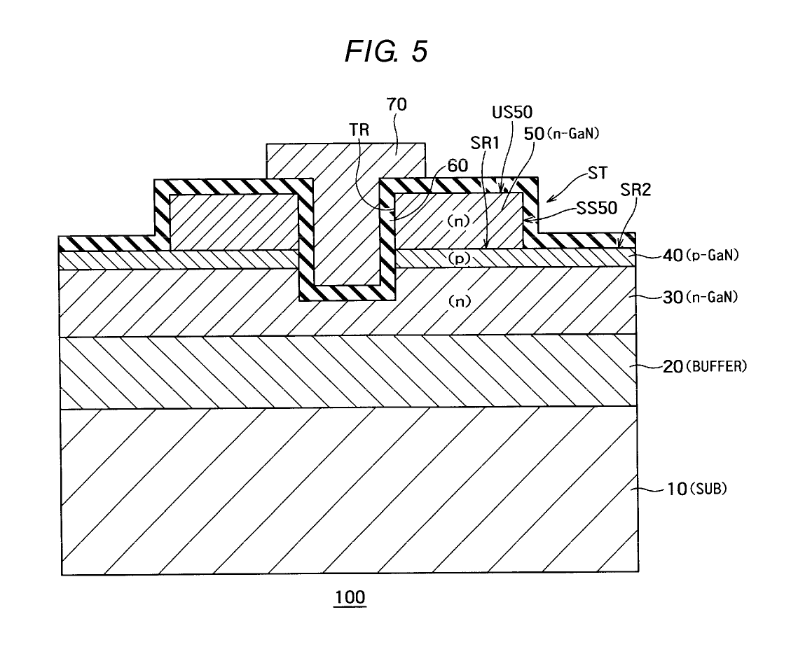

Next, as shown in FIG. 5, the gate insulator 60 is deposited on an inner surface of the trench TR, the front surface US50 and the side surfaces SS50 of the n-type GaN layer 50, and the second region SR2 of the surface of the p-type GaN layer 40.

Then, a material for forming the gate electrode 70 is embedded in the trench TR. The material for forming the gate electrode 70 is processed using a lithography technique and an etching technique. Due to such processing, the gate electrode 70 is formed as shown in FIG. 5. The gate electrode 70 is formed such that the gate electrode 70 penetrates the p-type GaN layer 40 from the front surface US50 of the n-type GaN layer 50 and reaches the n-type GaN layer 30. That is, the gate electrode 70 is formed such that one end of the gate electrode 70 is disposed above the surface US50 of the n-type GaN layer 50 and the other end of the gate electrode 70 is disposed in the inside of the n-type GaN layer 30 through the p-type GaN layer 40. The gate electrode 70 is insulated from the n-type GaN layer 50, the p-type GaN layer 40 and the n-type GaN layer 30 by the gate insulator 60.

Next, when necessary, after the interlayer insulator 80 is deposited, a contact hole is formed in the front surface US50 of the n-type GaN layer 50 using a lithography technique and an etching technique. Subsequently, after a material for forming the source electrode 90 is deposited, the material for forming the source electrode 90 is processed by a lithography technique and an etching technique. Due to such processing, as shown in FIG. 1, the source electrode 90 is formed on the front surface US50 of the n-type GaN layer 50.

Next, when necessary, after the interlayer insulator 80 is deposited again, a contact hole is formed on the second region SR2 of the surface of the p-type GaN layer 40 using a lithography technique and an etching technique. Subsequently, after a material for forming the charge pull-out electrode 95 is deposited, the material for forming the charge pull-out electrode 95 is processed using a lithography technique and an etching technique. Due to such processing, as shown in FIG. 1, the charge pull-out electrode 95 is formed on the second region SR2 of the p-type GaN layer 40.

As described above, the source electrode 90 is formed on the front surface US50 of the n-type GaN layer 50 (the upper step of the stepped portion ST), and the charge pull-out electrode 95 is formed on the second region SR2 of the p-type GaN layer 40 (the lower step of the stepped portion ST).

Next, the drain electrode 99 is formed on the back surface of the substrate 10. With such a step, the manufacture of the semiconductor device 100 shown in FIG. 1 is completed.

According to this embodiment, the n-type GaN layer 50 is selectively epitaxially grown on the first region SR1 of the surface of the p-type GaN layer 40. Due to such processing, the stepped portion ST is formed where the second region SR2 of the surface of the p-type GaN layer 40 forms the lower step and the front surface US50 of the n-type GaN layer 50 forms the upper step. Due to the presence of the stepped portion ST, the source electrode 90 can be formed on the front surface US50 of the n-type GaN layer 50 (the upper step of the stepped portion ST), and the charge pull-out electrode 95 can be formed on the second region SR2 of the p-type GaN layer 40 (the lower step of the stepped portion ST). That is, the regions where the source electrode 90 is formed and the region where the charge pull-out electrode 95 is formed can be ensured thus facilitating the formation of the source electrode 90 and the charge pull-out electrode 95. Accordingly, the occurrence of avalanche breakdown can be suppressed and hence, the semiconductor device 100 can maintain high breakdown voltage.

Further, the n-type GaN layer 50 is selectively epitaxially grown on the p-type GaN layer 40. Due to such processing, the region where the charge pull-out electrode 95 is formed can be ensured and, at the same time, the resistance of the n-type GaN layer 50 can be lowered. As a result, the semiconductor device 100 according to this embodiment can realize both the high breakdown voltage and the low ON resistance.

### (Modification 1)

In the above-mentioned embodiment, the buffer layer 20 has the superlattice structure where the layer made of AlN and the layer made of GaN are alternately laminated or is formed of the composition gradient AlGaN layer where an Al content ratio in AlGaN is gradually changed. In this modification, Si or Ge is introduced into such a buffer layer 20.

When the substrate 10 is a silicon substrate, there exists a possibility that silicon is diffused in a bottom portion of the buffer layer 20. Further, the n-type GaN layer 30 formed on the buffer layer 20 contains Si or Ge so that there exists a possibility that silicon is diffused also in an upper portion of the buffer layer 20. That is, it is considered that the bottom portion and the upper portion of the buffer layer 20 are formed into an n-type layer.

In this modification, Si or Ge is introduced also into an intermediate portion (intermediate layer) of the buffer layer 20. Due to such processing, the intermediate portion of the buffer layer 20 also has the n-type superlattice structure or is also formed into an n-type composition gradient AlGaN layer. By forming the whole buffer layer 20 into an n type, the resistance of the buffer layer 20 is lowered. Since the semiconductor device 100 is a vertical FET, by lowering the resistance of the buffer layer 20, the ON resistance of the semiconductor layer 100 can be further lowered. An n-type impurity may be introduced into the buffer layer 20 at the time of forming the buffer layer 20.

### (Modification 2)

The source electrode 90 and the charge pull-out electrode 95 may be formed using the same material provided that the source electrode 90 and the charge pull-out electrode 95 are allowed to be connected with the p-type GaN layer 40 and the n-type GaN layer 50 by ohmic bonding. In this case, it is unnecessary to form a contact hole in the source electrode 90 and the charge pull-out electrode 95 individually, and it is sufficient to form a contact hole for the source electrode 90 and the charge pull-out electrode 95 in common. In this case, the deposition and processing of a material for forming the electrode can be performed in common. Accordingly, the number of times of lithography steps and the number of times of etching steps may be decreased thus decreasing the number of manufacturing steps.

In general, it is often the case where a voltage of the source electrode 90 and a voltage of the charge pull-out electrode 95 are set equal. Accordingly, there arises no problem even when an electrode is used in common by the source electrode 90 and the charge pull-out electrode 95. The modification 2 can be combined with the modification 1.

### Second Embodiment

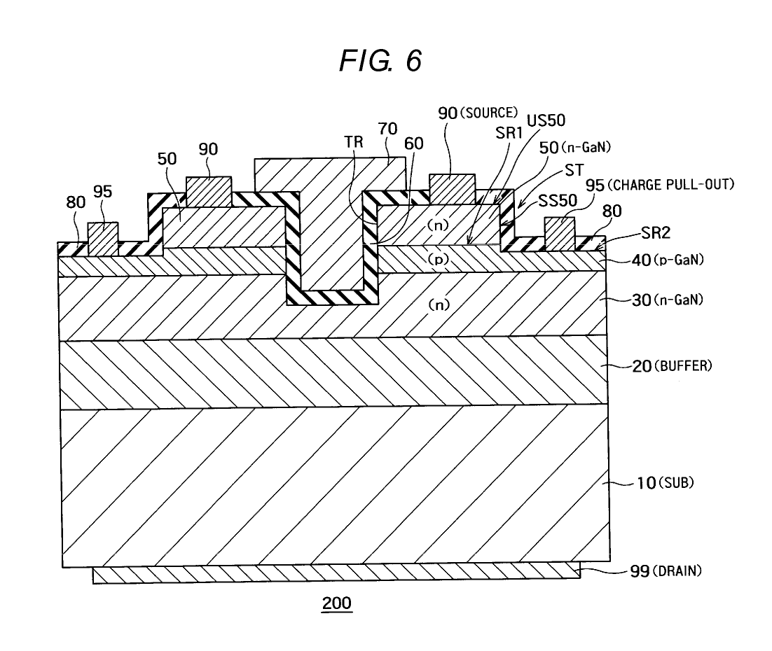

FIG. 6 is a cross-sectional view showing one example configuration of a vertical GaN semiconductor device 200 (hereinafter, also referred to as a semiconductor device 200) according to a second embodiment. In the semiconductor device 200 according to the second embodiment, a lower portion of a side surface SS of a stepped portion ST is formed of a p-type GaN layer 40, and an upper portion of the side surface SS of the stepped portion ST is formed of an n-type GaN layer 50. That is, an upper portion of the p-type GaN layer 40 is removed. Other constitutions of the second embodiment may be substantially equal to the corresponding constitutions of the first embodiment.

Also in the semiconductor device 200 according to the second embodiment, due to the presence of the stepped portion ST, a source electrode 90 can be formed on a front surface US50 of the n-type GaN layer 50 (an upper step of the stepped portion ST), and a charge pull-out electrode 95 can be formed on a second region SR2 of the p-type GaN layer 40 (a lower step of the stepped portion ST). In this embodiment, the n-type GaN layer 50 is epitaxially grown on the p-type GaN layer 40. Accordingly, the second embodiment may acquire the substantially same advantageous effects as the first embodiment.

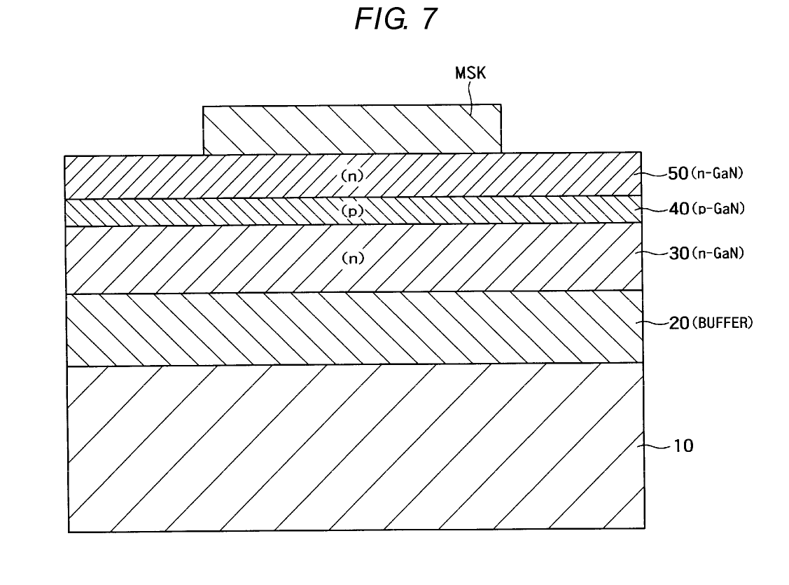

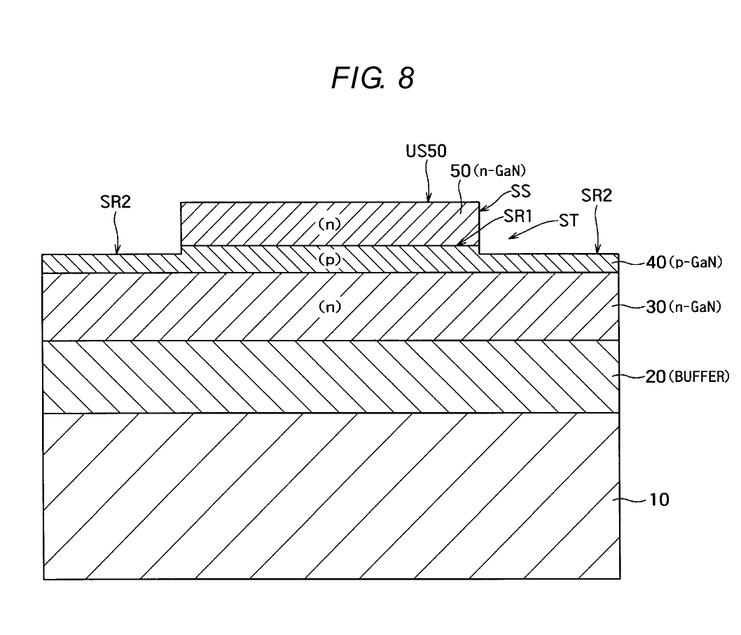

FIG. 7 and FIG. 8 are cross-sectional views showing one example of a method of manufacturing the semiconductor device 200 according to the second embodiment.

Firstly, in the same manner as the first embodiment, the structure shown in FIG. 2 is acquired. Next, GaN is epitaxially grown on the p-type GaN layer 40 while being doped with an n-type impurity (for example, Si, Ge).

Next, a mask layer MSK is formed on the n-type GaN layer 50 using a lithography technique and an etching technique. The mask layer MSK is made to remain on a region where the n-type GaN layer 50 is formed, and the mask layer MSK is removed in a region (second region SR2) other than the region where the n-type GaN layer 50 is formed. Due to such processing, the structure shown in FIG. 7 can be acquired.

Next, the n-type GaN layer 50 is etched by using the mask layer MSK as a mask. Due to such etching, a material layer for forming the n-type GaN layer 50 on the second region SR2 of the surface of the p-type GaN layer 40 is selectively removed. As a result, the stepped portion ST is formed where the second region SR2 of the p-type GaN layer 40 forms a lower step and the surface US50 of the n-type GaN layer 50 forms an upper step. Further, in such an etching step, not only the n-type GaN layer 50 but also the upper portion of the p-type GaN layer 40 are overetched. Accordingly, as shown in FIG. 8, an upper portion of the side surface SS of the stepped portion ST is formed of the n-type GaN layer 50, and a lower portion of the side surface SS of the stepped portion ST is formed of the p-type GaN layer.

Then, in the same manner as the first embodiment, a trench TR, a gate insulator 60, a gate electrode 70, a source electrode 90, and a charge pull-out electrode 95 are formed. Due to such processing, the manufacture of the semiconductor device 200 shown in FIG. 6 is completed.

According to the second embodiment, after the n-type GaN layer 50 is epitaxially grown on the whole surface of the p-type GaN layer 40, the n-type GaN layer 50 is selectively etched using the mask layer MSK. Due to such processing, in the same manner as the first embodiment, the stepped portion ST is formed. Since the n-type GaN layer 50 is selectively etched, the upper portion of the p-type GaN layer 40 is overetched. Accordingly, the n-type GaN layer 50 appears on the upper portion of the side surface SS of the stepped portion ST, and the p-type GaN layer 40 appears on the lower portion of the side surface SS of the stepped portion ST.

In this manner, the stepped portion ST can be formed by also selectively etching the n-type GaN layer 50 which is epitaxially grown. Accordingly, the second embodiment may acquire the substantially same advantageous effects as the first embodiment.

Further, according to the second embodiment, after the p-type GaN layer 40 is formed, the n-type GaN layer 50 can be formed continuously. Accordingly, the intrusion of particles or the like between the p-type GaN layer 40 and the n-type GaN layer 50 can be suppressed.

Further, the above-mentioned modifications 1, 2 may be combined with the second embodiment.

### Third Embodiment

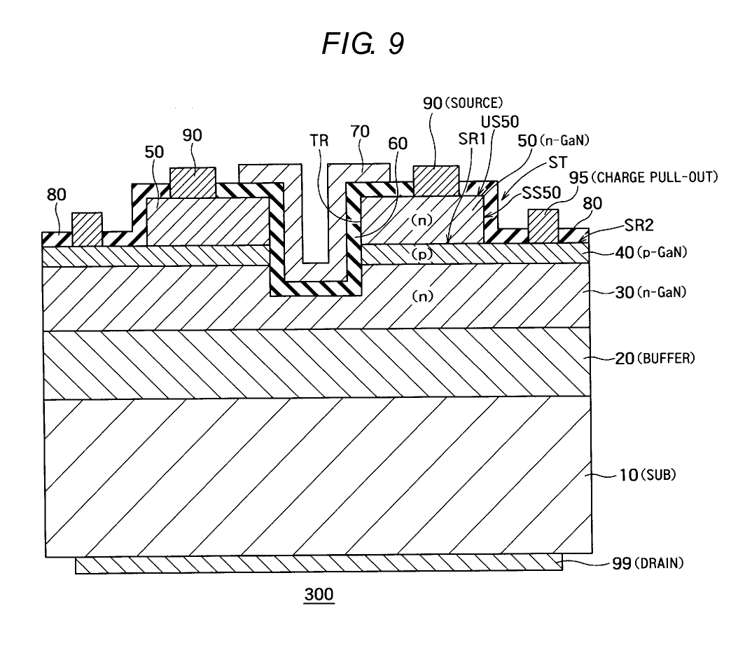

FIG. 9 is a cross-sectional view showing one example configuration of a vertical GaN semiconductor device 300 (hereinafter, also referred to as a semiconductor device 300) according to a third embodiment. In the semiconductor device 300 according to the third embodiment, a gate electrode 70 is not completely embedded in a trench TR. However, the gate electrode 70 covers an inner surface of the trench TR by way of a gate insulator 60. The other constitutions of the third embodiment may be substantially equal to the corresponding constitutions of the first embodiment. Accordingly, the third embodiment may acquire the substantially same advantageous effects as the first embodiment. Further, the third embodiment can be combined with the modifications 1, 2 and/or the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first layer made of a group III nitride semiconductor of a first conductivity type;
a second layer made of a group III nitride semiconductor of a second conductivity type on a first surface of the first layer;
a third layer made of a group III nitride semiconductor of the first conductivity type on a first region of a surface of the second layer;
a gate electrode extending through the second layer and the third layer and the first surface of the first layer and insulated from the first layer, the second layer and the third layer;
a first electrode in contact with the third layer;
a second electrode in contact with a second region of the surface of the second layer that is different from the first region; and
a third electrode provided on a side of a second surface of the first layer that is opposite to the first surface.

2. The semiconductor device according to claim 1, wherein a contact region between the first electrode and the third layer is higher than a contact region between the second electrode and the second layer.

3. The semiconductor device according to claim 1, wherein
the second layer has a stepped portion, the stepped portion including an upper step, a lower step, and a side portion connecting the upper step and the lower step, the third layer being provided on the upper step of the stepped portion, and the second electrode being provided on the lower step of the stepped portion.

4. The semiconductor device according to claim 1, wherein the first electrode and the second electrode are made of the same material.

5. The semiconductor device according to claim 1, further comprising:
a buffer layer between the first layer and the third electrode, wherein
the buffer layer has a superlattice structure in which Si or Ge is contained in an intermediate portion of the buffer layer.

6. The semiconductor device according to claim 5, wherein the buffer layer includes a layer of AlN and a layer of GaN that are laminated to each other.

7. The semiconductor device according to claim 5, wherein the buffer layer includes a layer of AlGaN in which Al content ratio is gradually lowered along the direction from the first surface of the substrate toward the first layer.

8. The semiconductor device according to claim 1, wherein the gate electrode fills a trench that is formed through the second layer and the third layer and the surface of the first layer and lined with an insulating layer.

9. The semiconductor device according to claim 1, wherein the gate electrode has an open section through a center portion thereof.

10. A semiconductor device comprising:
a first layer made of a group III nitride semiconductor of a first conductivity type;
a second layer made of a group III nitride semiconductor of a second conductivity type on the first layer;
a third layer made of a group III nitride semiconductor of the first conductivity type on the second layer;
a gate electrode extending through the second layer and the third layer and a surface of the first layer, and insulated from the first layer, the second layer and the third layer;
a first electrode in contact with the third layer;
a second electrode in contact with the second layer; and
a third electrode electrically connected to the first layer,
wherein a contact interface region between the first electrode and the third layer is at a first level and a contact interface region between the second electrode and the second layer is at a second level that is different from the first level.

11. The semiconductor device according to claim 10, wherein
the second layer has a stepped portion, the stepped portion including an upper step, a lower step, and a side portion connecting the upper step and the lower step, the third layer being provided on the upper step of the stepped portion, and the second electrode being provided on the lower step of the stepped portion.

12. The semiconductor device according to claim 10, wherein the gate electrode fills a trench that is formed through the second layer and the third layer and the surface of the first layer and lined with an insulating layer.

13. The semiconductor device according to claim 10, wherein the gate electrode has an open section through a center portion thereof.

14. A method of manufacturing a semiconductor device comprising:
forming a first layer using a group III nitride semiconductor of a first conductivity type;
forming a second layer on a first surface of the first layer using a group III nitride semiconductor of a second conductivity type;
forming a third layer on a first region of the second layer using a group III nitride semiconductor of the first conductivity type;
forming a gate electrode which penetrates through the second layer, the third layer, and a surface of the first layer, and is insulated from the first layer, the second layer and the third layer;
forming a first electrode on the third layer;
forming a second electrode on a second region of the second layer that is different from the first region; and
forming a third electrode on a side of a second surface of the first layer that is opposite to the first surface,
wherein a contact interface region between the first electrode and the third layer is at a first level and a contact interface region between the second electrode and the second layer is at a second level that is different from the first level.

15. The method of manufacturing a semiconductor device according to claim 14, wherein the third layer is epitaxially grown on the first region of the second layer.

16. The method of manufacturing a semiconductor device according to claim 15, further comprising:
prior to the gate electrode is formed, forming a trench through the second layer and the third layer and a surface of the first layer and forming an insulating layer on sidewalls and a bottom of the trench and on the third region of the second layer.

17. The method of manufacturing a semiconductor device according to claim 16, wherein the first electrode is formed through the insulating layer and the second electrode is formed through the insulating layer.

18. The method of manufacturing a semiconductor device according to claim 17, wherein the first electrode and the second electrode are formed separately in two steps.

19. The method of manufacturing a semiconductor device according to claim 17, wherein the first electrode and the second electrode are formed at the same time in a single step.

20. The method of manufacturing a semiconductor device according to claim 17, wherein the second layer is formed with a stepped portion, the stepped portion including an upper step, a lower step, and a side portion connecting the upper step and the lower step, the third layer being formed on the upper step of the stepped portion, and the second electrode being formed on the lower step of the stepped portion.
